(19) United States
(12) Patent Application Publication
(10) Pub. No.: US 2009/0294155 A1
(43) Pub. Date: Dec. 3, 2009

(54) FLEXIBLE PRINTED CIRCUIT BOARD, SHIELD PROCESSING METHOD FOR THE CIRCUIT BOARD AND ELECTRONIC APPARATUS

(75) Inventors: Daigo SUZUKI, Yokohama-shi (JP); Kiyomi MURO, Hachioji-shi (JP); Terunari KANO, Hamura-shi (JP); Gen FUKAYA, Nishitama-gun (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/475,324

(22) Filed: May 29, 2009

(30) Foreign Application Priority Data
May 29, 2008 (JP) 2008-141481

(51) Int. Cl. H05K 1/00; H05K 3/10

(52) U.S. Cl. 174/254; 29/846

(57) ABSTRACT

According to one embodiment, there is provided a flexible printed circuit board including a base layer, a signal layer formed on a surface of the base layer, a cover layer covering the signal layer, a connecting pattern portion formed in the signal layer, an opening formed in the cover layer and surrounds periphery of the connecting pattern portion, a conductive shield material covering the cover layer in which part of the conductive shield material fills the opening, thereby adhering to an upper face and sides of the connecting pattern portion, and a protective layer covering the conductive shield material.

### CROSS-REFERENCE TO RELATED APPLICATIONS

This application is based upon and claims the benefit of priority from Japanese Patent Application No. 2008-141481, filed May 29, 2008, the entire contents of which are incorporated herein by reference.

### BACKGROUND

1. Field

One embodiment of the invention relates to flexible printed circuit boards that handle high frequency signals.

2. Description of the Related Art

Flexible printed circuit boards that can be flexibly mounted in housings and that have a high degree of freedom in wiring have been increasingly used in information processing apparatuses. Due to the higher speed of processing in information processing apparatuses and the higher density of circuits, flexible printed circuit boards mounted in the housings of the devices require electromagnetic shield structures. An electromagnetic shield structure forms an electromagnetic shield layer of low impedance between the power source ground (GND) and the printed circuit board, taking account of any transfer loss of high frequency signals to be used, and of noise. Such an electromagnetic shield structure is actualized by conductively connecting an electromagnetic shield layer to a ground pattern of the same potential as the grounding potential of the power source. This type of electromagnetic shield structure has been disclosed in, for example, Jpn. Pat. Appln. KOKAI Publication No. 5-283888, in which a recess is formed in the electromagnetic shield layer, the recess is filled with a jumper member, and this jumper member conductively connects an electromagnetic shield layer to the upper face of a grounding land.

A conventional electromagnetic shield structure in which an electromagnetic shield layer is conductively connected to a ground pattern of the same potential as the grounding potential of a power source is a structure in which the electromagnetic shield layer is conductively connected to the surface of the ground pattern. Therefore, the ground connection structure of the electromagnetic shield layer is fragile and is not highly reliable in a flexible printed circuit board that may be subject to bending.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional view of the configuration of the main part of a flexible printed circuit board according to a first embodiment of the invention;

FIG. 2 is an exemplary schematic view of the configuration of the main part of the flexible printed circuit board according to the first embodiment;

FIG. 3 is an exemplary sectional view illustrating a process for manufacturing the flexible printed circuit board according to the first embodiment;

FIG. 4 is an exemplary sectional view illustrating a process for manufacturing the flexible printed circuit board according to the first embodiment;

FIG. 5 is an exemplary sectional view illustrating a process for manufacturing the flexible printed circuit board according to the first embodiment;

FIG. 6 is an exemplary schematic view of the configuration of the main part of the flexible printed circuit board according to the first embodiment, over a wide area extending from the ground pattern area;

FIG. 7 is an exemplary sectional view of the configuration of the main part of the flexible printed circuit board according to the first embodiment, over a wide area extending from the ground pattern area;

FIG. 8 is an exemplary schematic view of the configuration of the main part of the flexible printed circuit board according to the first embodiment, over a wide area extending from the ground pattern area;

FIG. 9 is an exemplary sectional view of the configuration of the main part of a flexible printed circuit board according to a second embodiment of the invention;

FIG. 10 is an exemplary sectional view of the configuration of the main part of a flexible printed circuit board according to a third embodiment of the invention;

FIG. 11 is an exemplary sectional view of the configuration of the main part of a flexible printed circuit board according to a fourth embodiment of the invention;

FIG. 12 is an exemplary perspective view of the appearance of a portable computer according to a fifth embodiment of the invention;

FIG. 13 is an exemplary perspective view of the main body of the portable computer according to the fifth embodiment, from which a keyboard has been detached;

FIG. 14 is an exemplary perspective view of the hard disk drive of the portable computer according to the fifth embodiment and a case supporting the hard disk drive, as viewed from obliquely below;

FIG. 15 is an exemplary perspective view of the hard disk drive of the portable computer according to the fifth embodiment and the case supporting the hard disk drive, as viewed from obliquely above;

FIG. 16 is an exemplary side view of a flexible printed circuit board laid in the portable computer according to the fifth embodiment; and

FIG. 17 is an exemplary perspective view of a part of the main body of a portable computer according to the fifth embodiment, from which a keyboard, a hard disk drive, and a case have been detached.

### DETAILED DESCRIPTION

Various embodiments according to the invention will be described hereinafter with reference to the accompanying drawings. In general, according to one embodiment of the invention, there is provided a flexible printed circuit board comprising: a base layer; a signal layer formed on a surface of the base layer; a cover layer covering the signal layer; a connecting pattern portion formed in the signal layer; an opening formed in the cover layer and surrounds periphery of the connecting pattern portion; a conductive shield material covering the cover layer in which part of the conductive shield material fills the opening, thereby adhering to an upper face and sides of the connecting pattern portion; and a protective layer covering the conductive shield material.

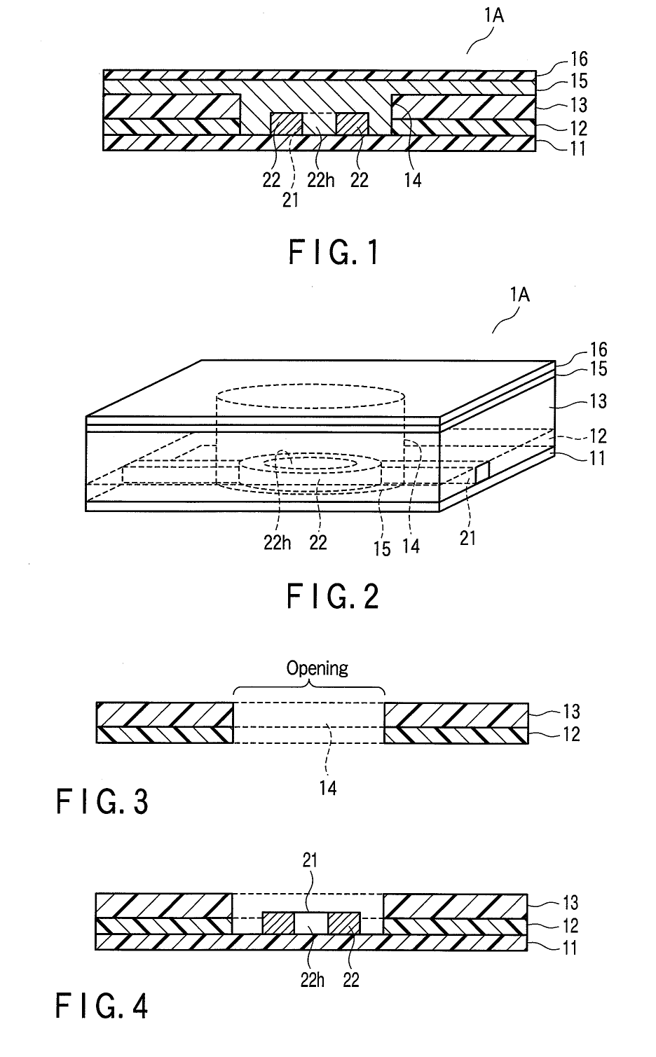

FIGS. 1 and 2 show the configuration of the main part of a flexible printed circuit board according to the first embodiment of the invention. As shown in FIGS. 1 and 2, the flexible printed circuit board 1A according to the first embodiment of the invention comprises: a base layer 11; a signal layer 12 formed on the surface of the base layer 11; a cover layer 13 covering the signal layer 12; a connecting pattern portion 22 formed in the signal layer 12; an opening 14 formed in the cover layer 13 and surrounding the periphery of the connecting pattern portion 22; a conductive shield material 15 covering the cover layer 13 such that part of the conductive shield material 15 fills the opening 14, thereby adhering to the upper face and sides of the connecting pattern portion 22; and a protective layer 16 covering the conductive shield material 15.

The base layer 11 is formed from a flat insulation film (e.g., polyimide film).

A copper foil pattern is formed in the signal layer 12 by an etching process. The signal layer 12 includes a coverlay adhesive for joining the cover layer 13 to the base layer 11. In the first embodiment, the connecting pattern portion 22 is formed in the signal layer 12. This connecting pattern portion 22 comprises a pattern land (hereinafter, pattern land 22) for the ground pattern 21 formed in the signal layer 12. The pattern land 22 has in its central area a land inner hole 22h that is open depthwise. Part of the conductive shield material 15 adheres to the upper face and sides of the pattern land 22 as well as the internal face of the land inner hole 22h.

When the flexible printed circuit board 1A is mounted on an electronic apparatus and is connected in circuit, the ground pattern 21 is set to the ground potential (grounding potential) required for the electronic apparatus.

Following a pattern layout in the signal layer 12, an opening 14 is previously formed through the cover layer 13 before a laminating process of the cover layer 13. During the laminating process, the conductive shield material 15 flows into and fills the opening. The diameter of this opening 14 is greater than that of the pattern land 22 for the ground pattern 21 in the signal layer 12 such that a predetermined quantity of conductive shield material 15 can be injected between the periphery of the pattern land 22 and this opening 14.

The conductive shield material 15 is provided in the form of a conductive paste material (e.g., silver paste) of predetermined viscosity, and forms a conductive shield layer for the signal layer 12. This conductive shield material 15 forms a conductive shield layer such that a portion covering the cover layer 13 and a portion filling the opening 14 are integrated.

The flexible printed circuit board 1A according to the first embodiment described above includes an electromagnetic shield layer that has a conductive connecting structure in which part of the conductive shield material 15 adheres to the upper face and sides of the pattern land 22. Accordingly, compared to the case where a shield material is conductively connected only to the upper face of the pattern land, this printed circuit board 1A increases a joint area with the conductive shield material 15. In addition, the conductive shield material 15 is disposed in contact with the land not only in the planar direction of the land but also along the entire circumference of the land, thus maintaining robust joint strength in the direction of bending of the flexible printed circuit board 1A.

Referring to FIGS. 3 to 5, next will be described a process for manufacturing the foregoing flexible printed circuit board 1A. In the description of the process for manufacturing, the step of forming in a signal layer 12 various conductive patterns including a wiring pattern (i.e., etching step) will be omitted. Accordingly, it is assumed that the ground pattern 21 and the pattern land 22 with an inner hole 22h formed in it have already been formed in the signal layer 12 disposed on the base layer 11.

In step 1 shown in FIG. 3, following the pattern layout of the signal layer 12, an opening 14 of a diameter greater than the diameter of the pattern land 22 is formed through so as to correspond to the pattern land 22 of the ground pattern 21.

In step 2 shown in FIG. 4, a base layer 11 with the signal layer 12 formed thereon and a cover layer 13 are bonded together via a coverlay adhesive; at this time, the ground pattern 21 and the pattern land 22 with the inner hole 22h made in it have already been formed in the signal layer 12, and the opening 14 greater in diameter than the pattern land 22 has already been formed in the cover layer 13.

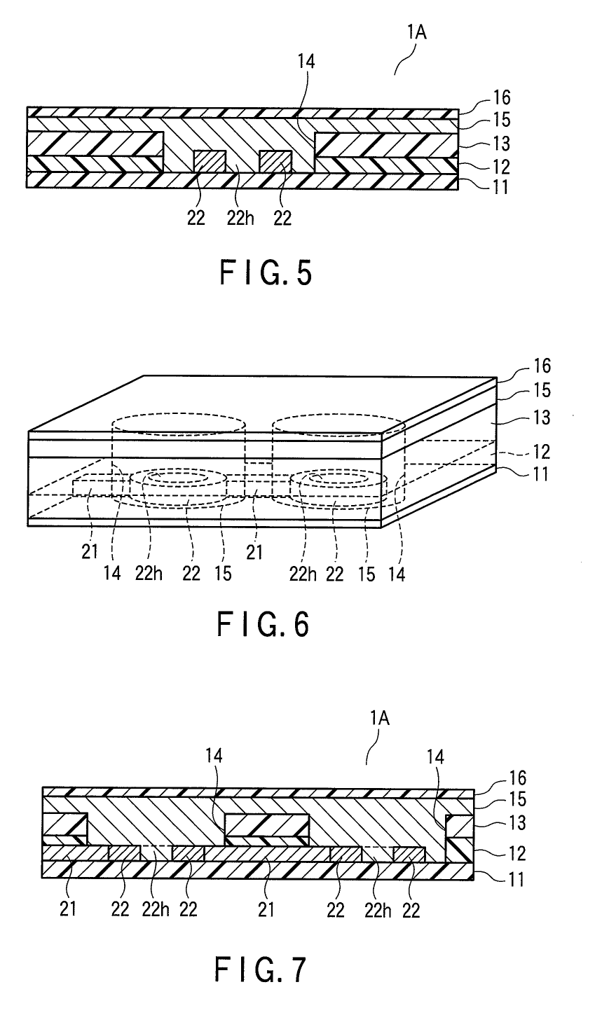

In step 3 shown in FIG. 5, the conductive shield material 15 is caused to flow over the cover layer 13 on which the base layer 11 has been bonded in the step 2. After the conductive shield material 15 is spread over the cover layer 13, a protective layer 16 is formed over the conductive shield material 15. Specifically, in step 3, the conductive shield material 15 covers the cover layer 13 and, further, some of the conductive shield material 15 flows into the opening 14 in the cover layer 13; the conductive shield material 15 that has flowed into the opening 14 adheres to the ground pattern 21 and the upper face and sides of the pattern land 22 (all of which are exposed in the opening 14), as well as the internal face of the land inner hole 22h; thus the conductive shield material 15 fills the opening 14.

Thus, a flexible printed circuit board 1A can be manufactured capable of maintaining robust joint strength in the direction of bending.

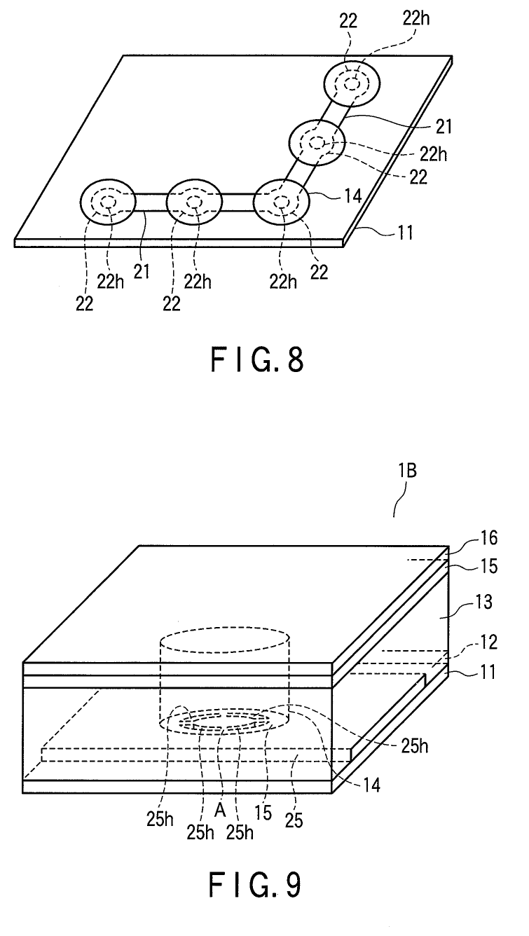

The first embodiment has been described using an example where the ground pattern 21 has only one pattern land 22. However, in the actual pattern configuration, a number of pattern lands 22 are formed for the ground pattern at predetermined intervals. FIGS. 6 to 8 show examples of the arrangement of the pattern lands 22. FIG. 7 is a sectional view of the ground pattern (ground line) shown in FIG. 6. FIG. 8 is an example of the arrangement of ground pattern 21, pattern lands 22, and openings 14 over a wide area extending from the ground pattern area shown in FIGS. 6 and 7. In the example in FIG. 8, a number of pattern lands 22 are disposed at predetermined intervals on one ground pattern (i.e., along one ground line) 21. An opening 14 greater in diameter than the pattern land 22 is formed in the cover layer 13 so as to correspond to each of the pattern lands 22.

Thus, the conductive connecting structure of the electromagnetic shield layer, in which part of the conductive shield material 15 adheres to the upper face and sides of each of the pattern lands 22, has a notably increased joint area with the conductive shield material 15, which would not be the case where the shield material were conductively connected only to the upper face of the pattern land. Accordingly, robust joint strength can be maintained in the direction of bending.

FIGS. 9 to 11 show flexible printed circuit boards according to the second to fourth embodiments, respectively, of the invention, which differ from one another in the conductive connecting structure of the electromagnetic shield layer. In FIGS. 9 to 11, parts identical to those in the first embodiment described above with reference to FIGS. 1 and 2 are labeled with reference numerals identical to those used in FIGS. 1 and 2 and explanations of these parts are not repeated here.

In the flexible printed circuit board 1B (shown in FIG. 9) according to the second embodiment of the invention, the area where the end of an opening 14 in a cover layer 13 intersects the surface of a ground pattern 25 formed in the signal layer 12 is defined as a connecting pattern area A that conductively connects a conductive shield layer. A hole 25h is formed through the ground pattern 25 in part of the connecting pattern area A. Part of the conductive shield material 15 adheres to the connecting pattern area A as well as the internal face of the hole 25h. The connecting pattern area A shown in FIG. 9 has a plurality of holes 25h.

Compared to where the shield material is conductively connected only to the upper face of the ground pattern, the conductive connecting structure of an electromagnetic shield layer, shown in FIG. 9, has an increased joint area with the conductive shield material 15, thus making it possible to maintain robust joint strength in the direction of bending.

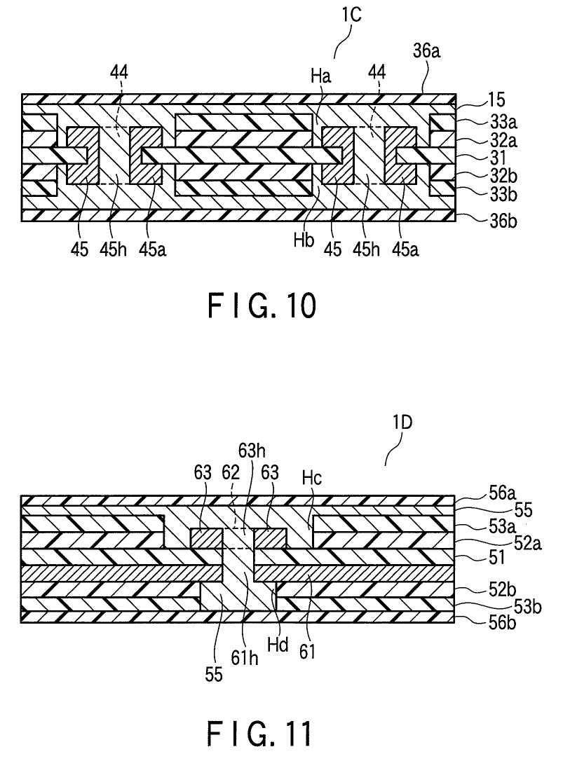

The flexible printed circuit board 1C (shown in FIG. 10) according to the third embodiment of the invention has signal layers on both sides of a base layer. That is, the so-called electromagnetic shield layer conductive connection technology of the invention is adopted on both FPCs such that a signal layer 32a, cover layer 33a, conductive shield material (electromagnetic shield layers) 15, and protective layer 36a are formed in that order on one side of the base layer 31, and a signal layer 32b, cover layer 33b, conductive shield material (electromagnetic shield layers) 15, and protective layer 36b are formed in that order on the other side of the base layer 31. In the flexible printed circuit board 1C shown in FIG. 10, the ground pattern 44 has connecting pattern portions 45 each of which has a via structure formed through the base layer 31. In the signal layers 32a and 32b, pattern lands 45a are formed at the ends of corresponding through holes 45h made through the corresponding connecting pattern portions 45. Formed in the cover layers 33a and 33b are openings Ha and Hb, respectively, which are greater in diameter than the land of each of the connecting pattern portions 45. A conductive shield material 15 forms a conductive shield layer integrally on each of the surface of the signal layers 32a and 32b such that, in the openings Ha and Hb respectively, part of the conductive shield material 15 adheres to the pattern lands 45a of the corresponding connecting pattern portions 45 as well as the inner walls of the through holes 45h.

In the conductive connecting structure of an electromagnetic shield layer shown in FIG. 10, part of the conductive shield material 15 adheres to the upper face and sides of each of the pattern lands 45a and the inner wall of the corresponding through hole 45h. Accordingly, robust joint strength can be maintained in the direction of bending.

In a flexible printed circuit board 1D (shown in FIG. 11) that has a double-sided FPC structure according to the fourth embodiment of the invention, a signal layer 52a, cover layer 53a, and protective layer 36a are formed in that order on one side of a base layer 51, and a signal layer 52b, cover layer 53b, and protective layer 36b are formed in that order on the other side of the base layer 51. In the flexible printed circuit board 1D shown in FIG. 11, a pattern land 63 for a ground pattern 62 is formed in the signal layer 52a on the one side; and a hole 63h is made through the base layer 51 in the middle of this pattern land 63. Formed in the signal layer 52b on the other side is a ground pattern (ground solid pattern) 61; and a hole 61h communicating with the hole 63h is formed on the ground solid pattern 61. In addition, an opening Hc greater in diameter than the pattern land 63 is formed on the cover layer 53a on the one side; and formed on the cover layer 53b on the other side is an opening Hd communicating with the opening Hc via the holes 63h and 61h.

In the conductive connecting structure of the electromagnetic shield layer shown in FIG. 11, part of the conductive shield material 55 adheres to the upper face and sides of the pattern land 63, also fills the communicating holes 63h and 61h, and further adheres to the face defining the opening of the ground solid pattern 61 and the face defining the end of this opening. This makes it possible to conductively connect the ground pattern 62 and ground pattern (the ground solid pattern) 61 of the signal layers 52a and 52b respectively with robust joint strength.

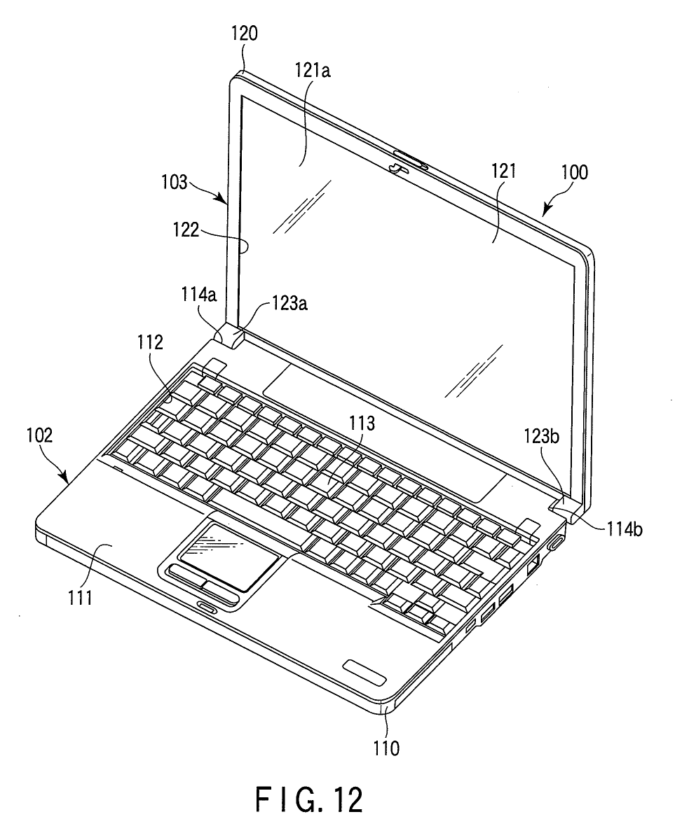

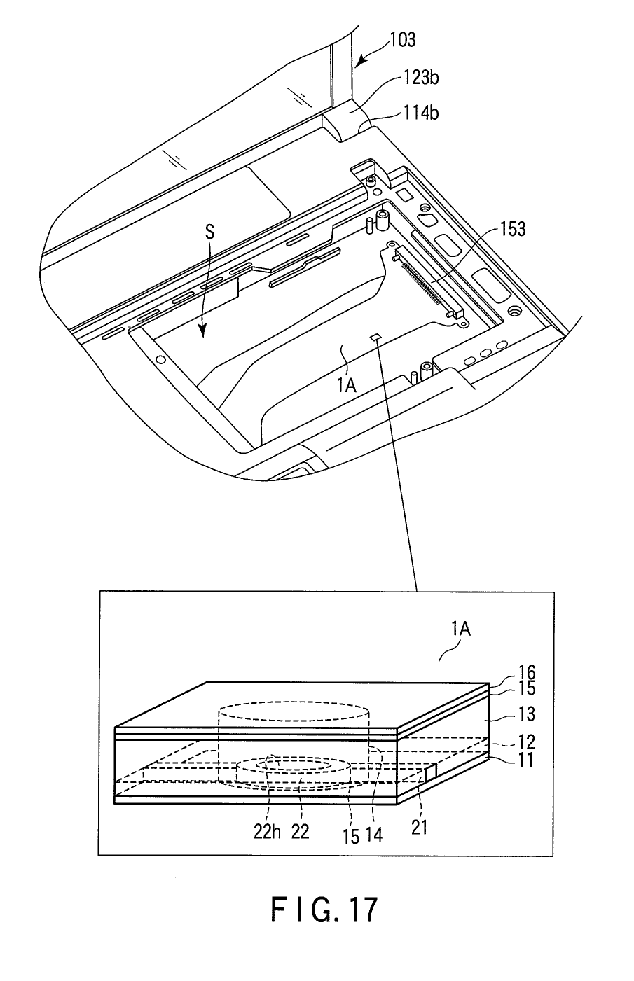

FIGS. 12 through 17 show the configuration of an electronic apparatus according to the fifth embodiment of the invention. The electronic apparatus uses as a compositional element the flexible printed circuit board 1A according to the foregoing first embodiment of the invention.

The electronic apparatus shown in FIGS. 12 through 17 actualizes a portable computer that transmits signals of serial advanced-technology-attachment 2 (SATA2) between the motherboard and the hard disk drive (HDD) by means of the flexible printed circuit board 1A shown in FIGS. 1 and 2.

FIG. 12 shows a notebook type portable computer 100. This portable computer 100 has a main body 102 and a display unit 103.

As shown in FIG. 12, the main body 102 has a first housing 110 that can be placed on a desk. The first housing 110 is in the form of a flat box and has a palm rest 111 and a keyboard mounting section 112 on its upper face. The palm rest 111 extends in the front half of the first housing 110 widthwise relative to the first housing 110. The keyboard mounting section 112 is located behind the palm rest 111. A keyboard 113 is attached to the keyboard mounting section 112.

The first housing 110 has at its rear a pair of display supports 114a and 114b interspatially disposed widthwise.

The display unit 103 has a second housing 120 and a display device, namely a liquid crystal display device 121. The second housing 120 is in the form of a flat box, and the display screen 121a of the liquid crystal display device 121 is exposed in an opening 122 provided for display.

The second housing 120 has a pair of legs 123a and 123b. These legs 123a and 123b are supported by the display supports 114a and 114b of the first housing 110 via hinges (not shown) so as to be freely rotatable. This rotating mechanism enables the display unit 103 to rotate between a closed position in which the display unit 103 covers the palm rest 111 and keyboard 113 from above and an open position in which the display unit 103 extends upward to expose the palm rest 111 and keyboard 113.

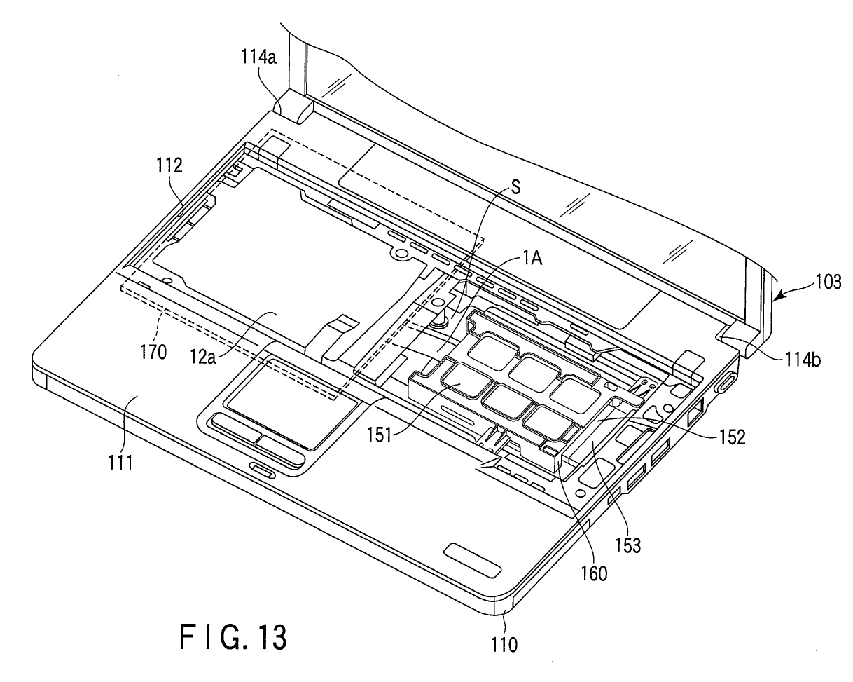

As shown in FIGS. 13, 16, and 17, defined below the place where the keyboard 113 is mounted on the keyboard mounting section 112 of the main body 102 is a space S for accommodating a hard disk drive 15 and motherboard 170 (described below) side by side.

In the space S of the main body 102, the motherboard 170 and the HDD 151 are mounted. The HDD 151 and the motherboard 170 access read/write data, via the transmission line of a differential signal, at a communication speed matching the specifications of SATA2.

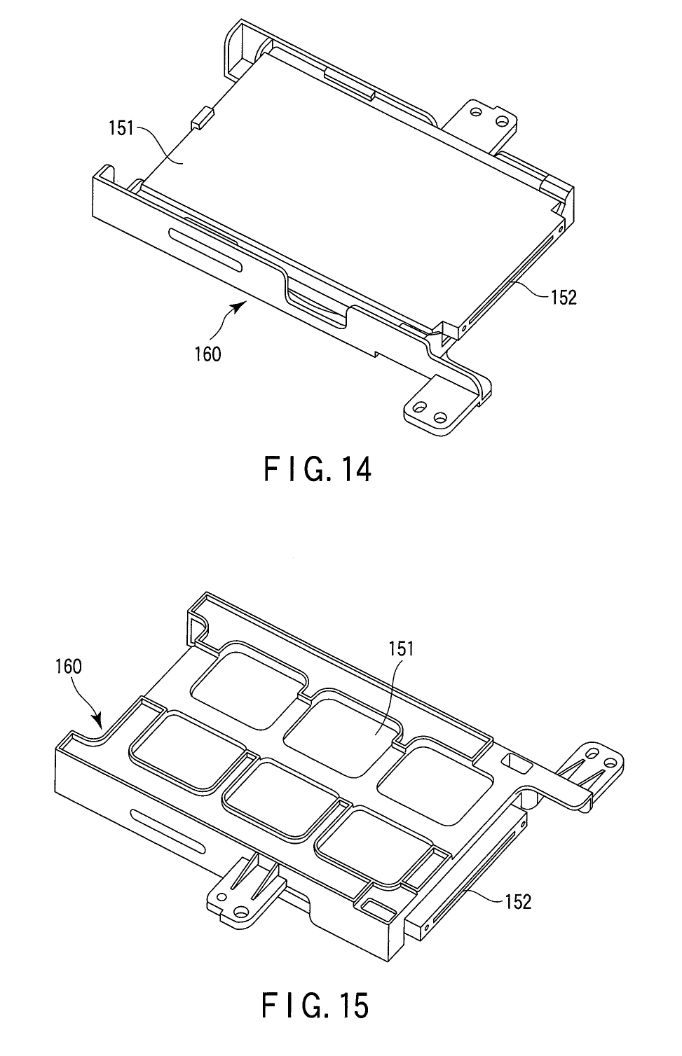

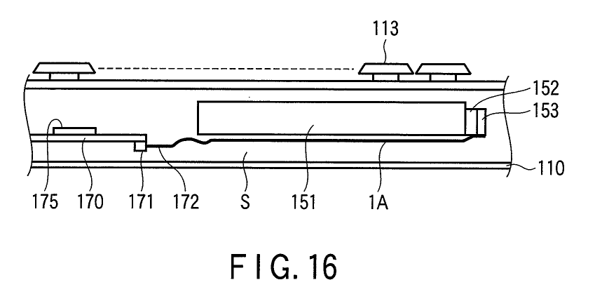

As shown in FIGS. 14 and 15, the hard disk drive 151 is mounted in the space S of the main body 102 with a fastening mechanism (not shown) so as to be held in a case 160. In FIG. 16, the case 160 holding the hard disk drive 151 is not shown. The motherboard 170 is mounted in the space S of the main body 102 with a fastening mechanism (not shown) so as to be parallel to the hard disk drive 151.

Mounted on the motherboard 170 are a CPU for controlling the system and a peripheral circuit for the CPU. Further, mounted on the peripheral circuit for the CPU is, for example, a south bridge IC 175 that comprises an I/O hub for connecting the hard disk drive 151 in circuit. Also, mounted on the motherboard 170 is a connector 171 (e.g., a connector with a pressure connection terminal of a lead insertion type) for connecting the hard disk drive 151 to the south bridge IC 175 in circuit.

The hard disk drive 151 is provided with a connector (in this example, a connector receptacle) 152 that comprises an interface mechanism for external connection.

The connector (connector receptacle) 152 of the hard disk drive 151 and the connector 171 (i.e., connector with the pressure connection terminal of the lead insertion type) mounted on the motherboard 170 are connected in circuit by the flexible printed circuit board 1A shown in FIGS. 1 and 2.

In the fifth embodiment, the flexible printed circuit board 1A connects in circuit the transmission ends of information processing elements, one of which is the external connection interface of the hard disk drive 151 and the other, the I/O connection interface of the motherboard 170. The external connection interface of the hard disk drive 151 is the connector (connector receptacle) 152; and the I/O connection interface of the motherboard 170 is the connector 171 (i.e., connector with the pressure connection terminal of lead insertion type) connected in circuit to the south bridge IC 175.

The wiring length of the flexible printed circuit board 1A applicable in the fifth embodiment extends from one side of the first housing 110 to substantially the middle of the housing. In the space S of the first housing 110, the flexible printed circuit board 1A is disposed along the back of the hard disk drive 151 and between the hard disk drive 151 and the motherboard 170 such that a narrow space (i.e., a narrow space except for a component mounting area) behind the hard disk drive 151 is utilized as a wiring path.

The flexible printed circuit board 1A has, at its one end in the wiring direction, a connector (connector plug) 153 connected to the connector (connector receptacle) 152 of the hard disk drive 151; it also has, at the other end in the wiring direction, a connector lead terminal 172 fitted to the connector 171 (i.e., connector with the pressure connection terminal of lead insertion type) mounted on the motherboard 170.

The flexible printed circuit board 1A is laid on the wiring path such that the connector (connector plug) 153 disposed at one end in the direction of wiring is connected to the connector (connector receptacle) 152 of the hard disk drive 151, and the connector lead terminal 172 disposed at the other end in the direction of wiring is fitted (i.e., connected under pressure) to the connector 171 (i.e., connector with the pressure connection terminal of lead insertion type) mounted on the motherboard 170.

Via this flexible printed circuit board 1A, read/write data is transmitted at a high speed matching SATA2, between the hard disk drive 151 and the south bridge IC 175 mounted on the motherboard 170.

This flexible printed circuit board 1A comprises: a base layer 11; a signal layer 12 formed on the base layer 11; a cover layer 13 covering the signal layer 12; a connecting pattern portion 22 disposed on the surface of the signal layer 12; an opening 14 formed in the cover layer 13 and surrounding the periphery of the connecting pattern portion 22; a conductive shield material 15 covering the cover layer 13 such that part of the conductive shield material 15 fills the opening 14, thereby adhering to the upper face and sides of the connecting pattern portion 22; and a protective layer 16 covering the conductive shield material 15. The signal layer 12 has a coverlay adhesive joining the cover layer 13 to the base layer 11. Formed in the signal layer 12 is a connecting pattern portion 22 for connecting an electromagnetic shield layer formed of the conductive shield material 15 to a ground pattern 21. This connecting pattern portion 22 comprises the pattern land (hereinafter, pattern land 22) for the ground pattern 21 formed in the signal layer 12. This pattern land 22 has in its central area a land inner hole 22h made depthwise. Part of the conductive shield material 15 adheres to the upper face and sides of the pattern land 22 as well as the internal face of the land inner hole 22h. The ground pattern 21 is maintained at the same potential as the ground potential (grounding potential) used in the device. The flexible printed circuit board 1A having a conductive connecting structure such as a conductive shield layer is a conductive connecting structure formed from an electromagnetic shield layer such that part of the conductive material 15 adheres to the upper face and sides of the pattern land 22. Accordingly, the flexible printed circuit board 1A has an increased joint area with the conductive shield material 15, compared to where the shield material is conductively connected only to the upper face of the pattern land. In addition, the conductive shield material 15 is disposed in contact with the land not only in the planar direction of the land but also along the entire circumference of the land, thus maintaining robust joint strength in the direction of bending of the flexible printed circuit board 1A. Using the flexible printed circuit board 1A as a signal transmission route for a high frequency circuit allows the realization of a highly reliable, high speed operating function that suppresses transmission loss and noise in the transfer of high frequency signals handled by a device.

As described above, the embodiments of the invention make it possible to provide: a flexible printed circuit board in which the joint strength of the conductive connecting part of an electromagnetic shield layer has been improved, a shield processing method for the printed circuit board, and an electronic apparatus.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A flexible printed circuit board comprising:
a base layer;
a signal layer on a surface of the base layer;
a cover layer on the signal layer;
a connecting pattern portion in the signal layer;
an opening in the cover layer surrounding periphery of the connecting pattern portion;
a conductive shield material on the cover layer comprising a portion of the conductive shield material filling the opening, and in contact with an upper face and sides of the connecting pattern portion; and
a protective layer on the conductive shield material.

2. The flexible printed circuit board of claim 1, wherein the connecting pattern portion comprises a land for a ground pattern in the signal layer.

3. The flexible printed circuit board of claim 2, wherein the land comprises a hole opening from the base layer in a direction intersecting the base layer, and a portion of the conductive shield material is in contact with the land comprising an inner surface of the hole.

4. The flexible printed circuit board of claim 3, wherein a plurality of lands is at the ground pattern at predetermined intervals.

5. The flexible printed circuit board of claim 1, wherein the connecting pattern portion is in an area where an end of the opening is configured to intersect a surface of a ground pattern in the signal layer, the connecting pattern portion comprises a hole through the ground pattern in the area, and a portion of the conductive shield material is in contact with to the area comprising an inner surface of the hole.

6. The flexible printed circuit board of claim 5, wherein a plurality of openings are in the area of the ground pattern.

7. The flexible printed circuit board of claim 1, wherein the signal layer, the cover layer, and the conductive shield material are on both sides of the base layer, and the connecting pattern portion through the base layer is configured to conductively connect the conductive shield materials on both sides of the base layer.

8. The flexible printed circuit board of claim 2, wherein the land comprises a through hole through the base layer and a portion of the conductive shield material is in contact with the land comprising the through hole.

9. A shield processing method for a flexible printed circuit board comprising a base layer, a signal layer, a cover layer, a conductive shield layer, and a protective layer in a laminated structure, the method comprising:
forming an opening in the cover layer, a diameter of the opening being longer than a diameter of a land pattern in the signal layer;
flowing a conductive shield material in the opening and causing the conductive shield material in contact with an upper face and sides of the land pattern; and
connecting the conductive shield material via the land pattern to a ground.

10. An electronic apparatus comprising:
a body;
a plurality of information processing modules in the body and comprising transmission terminals of high-frequency signals; and
a flexible printed circuit board comprising a signal transmission path between the transmission terminals of the information processing modules, the flexible printed circuit board comprising:
a base layer,
a signal layer on a surface of the base layer,
a cover layer on the signal layer,
a connecting pattern portion in the signal layer,
an opening in the cover layer surrounding periphery of the connecting pattern portion,
a conductive shield material on the cover layer comprising a portion of the conductive shield material filling the opening, and in contact with an upper face and sides of the connecting pattern portion, and
a protective layer on the conductive shield material, and
the conductive shield material being connected to a ground by the connecting pattern portion.
